(19) United States
(12) Patent Application Publication
(10) Pub. No.: US 2023/0301040 A1
(43) Pub. Date: Sep. 21, 2023

(54) COOLER FOR POWER MODULE AND METHOD OF MANUFACTURING SAME

(71) Applicants: Hyundai Motor Company, Seoul (KR); Kia Corporation, Seoul (KR)

(72) Inventor: Chang Soo Kim, Gunpo (KR)

(73) Assignees: Hyundai Motor Company, Seoul (KR); Kia Corporation, Seoul (KR)

(21) Appl. No.: 18/062,043

(22) Filed: Dec. 6, 2022

(30) Foreign Application Priority Data
Mar. 17, 2022 (KR) 10-2022-0059927

(51) Int. Cl. H05K 7/20

(52) U.S. Cl. CPC H05K 7/209

(57) ABSTRACT

Provided are a cooler for a power module, which has high thermal conductivity and can solve a problem about heterogeneous material bonding, and a method of manufacturing the same. The method includes forging a metal of a copper material to make the cooling fins, inserting and mounting the cooling fins into and in a cast metal mold, pouring molten metal including the aluminum alloy into the cast metal mold and casting the bonding body on outer sides of the cooling fins, and bonding the cast result to the housing including the aluminum alloy.

### CROSS REFERENCE TO RELATED APPLICATION

The present application claims the benefit of Korean Patent Application No. 10-2022-0059927, filed May 17, 2022, the entire contents of which are incorporated herein for all purposes by this reference.

### BACKGROUND

Technical Field

The present disclosure relates generally to a cooler for a power module and a method of manufacturing the same.

### Background

An inverter for an electric vehicle is a part in which a power module for electric power conversion functions as a key part, and dissipates much heat during operation, and thus a method of cooling the power module is important.

When the inverter is not properly cooled, the inverter may cause a serious problem in that, when a temperature of the power module exceeds a given level, the inverter causes a malfunction or a failure.

Thus, when a temperature at which the inverter is used is high, an expensive chip that is more excellent in high-temperature durability should be applied. If cooling efficiency can be improved, an effect of securing safety of a power module and an effect of saving a cost can be also expected by reducing a cost of the chip.

In recent, with the change into high efficiency/high performance of EV and HEV, a thermal load in the power module increases, and thus development of a higher efficient cooler is required.

Thus, in the conventional inverter, a cooler formed of an Al extrusion material, a cooler formed of an Al forged product, and a cooler formed of a Cu forged product was used.

However, in the case of the cooler formed of an Al extrusion material, there is a disadvantage in that it is difficult to obtain a cooling effect of high efficiency due to a restriction of the shape of a fluid channel in spite of ease of manufacturing and an advantage of low cost.

The cooler formed of an Al forged product has been developed on the purpose of securing cooling efficiency higher than that of the existing extrusion material cooler, and has implemented a cooling fin having a high density through a forging method. Thereby, the cooler formed of an Al forged product can increase an area capable of coming into contact with a coolant, and can increase cooling efficiency by adjusting a flow of the coolant through shapes and arrangement of the cooling fins. However, in the cooler formed of an Al forged product, a process of joining with the housing is very important because the cooler formed of an Al forged product should be made by forging the cooling fins, and should form fluid channels by joining the cooling fins to the housing.

The cooler formed of a Cu forged product can obtain higher cooling efficiency in spite of the cooling fins having the same shape by applying a Cu material having thermal conductivity higher than two times compared to Al. However, the cooler formed of a Cu forged product still suffers many difficulties when securing fusion strength and quality due to a difference in thermal conductivity and thermal expansion coefficient between Cu and Al in the event of junction with a housing including the Al material.

Therefore, under the background described above, the thermal load of the power module according to the recent high efficiency/performance of the EV and HEV increases, a development of a higher efficiency cooler is requested.

The foregoing is intended merely to aid in the understanding of the background of the present disclosure, and is not intended to mean that the present disclosure falls within the purview of the related art that is already known to those skilled in the art.

### SUMMARY

Accordingly, the present disclosure has been made keeping in mind the above problems occurring in the related art, and the present disclosure is intended to propose a cooler for a power module capable of solving a problem about bonding of a heterogeneous material and a housing of an Al material while having high thermal conductivity like a Cu forged cooler, and a method of manufacturing the same.

In one aspect, a cooler for a power module is provided , the cooler comprising: a) one or more cooling fins which comprise a body part which comprise 1) a copper material and comprising and 2) a protrusion; b) a bonding body comprising an inner side corresponding to a shape of a cooling fin protrusion so that cooling fin protrusions are coupled with the inner side; and c) a housing comprising an upper surface bonded with an outer side of the bonding body, and having a housing space formed therein.

In certain aspects, one or both of the bonding body and the housing are formed of materials comprising an aluminum alloy.

In a further aspect, a cooler for a power module is provided that suitably comprises: cooling fins, each of which includes a body part formed of a metal of a copper material and comprising a plate shape, and a protrusion protruding from an outer side of the body part; a bonding body formed of an aluminum alloy material, the bonding body comprising an inner side corresponding to the shape of the protrusion so that the protrusions are coupled with the inner side; and a housing formed of the same material as the aluminum alloy, the housing comprising an upper surface bonded with an outer side of the bonding body, and having a housing space formed therein.

The body part may have a plurality of first protrusions formed on an upper surface thereof so as to protrude at regular intervals.

The protrusions may be formed to protrude along a circumference of the body part on a lower side of the outer side on the whole.

The protrusions may be formed to protrude, with the cross section thereof being rectangular.

The protrusion may have one or more second protrusions on a lower surface.

The protrusion may have a plurality of second protrusions formed on a lower surface thereof at regular intervals.

The protrusion may have a curved surface in a form in which a part of a lower surface thereof is recessed at a given depth.

The bonding body may have a structure that encloses outer sides of the cooling fins.

The metal formed of a copper material may include an alloy formed of 99.9 wt % or more of copper (Cu) and 0.004 wt % or less of phosphorus (P).

The aluminum alloy may include an alloy formed of 1.5 to 3.5 wt % copper (Cu), 9.6 to 12.0 wt % silicon (Si), 0.3 wt % or less magnesium (Mg), 1.0 wt % or less zinc (Zn), 1.3 wt % or less iron (Fe), 0.5 wt % or less manganese (Mn), 0.5 wt % or less nickel (Ni), 0.3 wt % or less tin (Sn), and a balance of aluminum (Al).

The cooling fins may have thermal conductivity of 400 to 500 W/mK.

In the cooler for a power module, the first protrusion parts may be housed in the housing space.

In addition, a method of manufacturing a cooler for a power module according to the present disclosure is a method of manufacturing a cooler, and includes: forging a metal of a copper material to make the cooling fins; inserting and mounting the cooling fins into and in a cast metal mold; pouring molten metal including the aluminum alloy into the cast metal mold and casting the bonding body on outer sides of the cooling fins, thereby forming a cast product; and bonding the cast product to the housing including the aluminum alloy.

Further, the forging may be performed by preheating the forging die to a temperature of 200 to 300° C., and applying a forging pressure to 500 tons or higher.

The casting may use a die casting process.

The casting may be performed after heating the cooling fins at a temperature of 150° C. or higher.

The casting may be performed by preheating a temperature of the cast metal mold to 200 to 300° C., and applying a casting pressure up to 500 tons or higher.

The bonding of the housing may use brazing or laser welding.

In the bonding of the housing, the brazing may be performed at a temperature of 470 to 480° C.

In the bonding of the housing, the laser welding may be performed with an output of 2.8 to 4.5 kW.

The cooler for a power module according to the present disclosure uses the cooling fins having high thermal conductivity to reduce an operation temperature of the power module, and thereby it is possible to expect a cost saving effect through a reduction in the number of power modules or a down grade of the specification.

The cooler for a power module according to the present disclosure can improve bonding strength between the cooling fins and the housing through a specified shape.

A method of manufacturing a cooler for a power module according to the present disclosure includes: forging a metal of a copper material to make the cooling fins; insert casting a bonding body including the aluminum on outer sides of the cooling fins, thereby forming a cast product, and bonding the cast product to a housing including aluminum, and thereby it is possible to solve a problem about heterogeneous material bonding at the Cu forged cooler and the housing including an Al material.

In another embodiment, vehicles are provided that comprise an apparatus as disclosed herein.

The effects of the present disclosure are not limited to the foregoing. The effects of the present disclosure should be understood as including all the effects inferable form the following description.

### BRIEF DESCRIPTION OF THE DRAWINGS

The above and other objectives, features, and other advantages of the present disclosure will be more clearly understood from the following detailed description when taken in conjunction with the accompanying drawings, in which:

FIG. 1 is a figure schematically illustrating a cooler for a power module according to the present disclosure.

FIG. 2 is a schematic cross-sectional view of the cooler for a power module according to the present disclosure.

FIGS. 3A to 3C schematically illustrate a shape of a protrusion according to an exemplary embodiment of the present disclosure.

FIG. 4 is a flow chart showing a method of manufacturing a cooler for a power module according to the present disclosure.

FIGS. 5A to 5D illustrate the method of manufacturing a cooler for a power module according to the present disclosure step by step.

### DETAILED DESCRIPTION

It is understood that the term “vehicle” or “vehicular” or other similar term as used herein is inclusive of motor vehicles in general such as passenger automobiles including sports utility vehicles (SUV), buses, trucks, various commercial vehicles, watercraft including a variety of boats and ships, aircraft, and the like, and includes hybrid vehicles, electric vehicles, plug-in hybrid electric vehicles, hydrogen-powered vehicles and other alternative fuel vehicles (e.g. fuels derived from resources other than petroleum). As referred to herein, a hybrid vehicle is a vehicle that has two or more sources of power, for example both gasoline-powered and electric-powered vehicles.

The terminology used herein is for the purpose of describing particular embodiments only and is not intended to be limiting of the disclosure. As used herein, the singular forms “a,” “an” and “the” are intended to include the plural forms as well, unless the context clearly indicates otherwise. These terms are merely intended to distinguish one component from another component, and the terms do not limit the nature, sequence or order of the constituent components.

Unless specifically stated or obvious from context, as used herein, the term “about” is understood as within a range of normal tolerance in the art, for example within 2 standard deviations of the mean. “About” can be understood as within 10%, 9%, 8%, 7%, 6%, 5%, 4%, 3%, 2%, 1%, 0.5%, 0.1%, 0.05%, or 0.01% of the stated value. Unless otherwise clear from the context, all numerical values provided herein are modified by the term “about”.

These and other objects, features, and advantages of the present disclosure will become apparent from the following more detailed description and illustrative examples. However, the present disclosure may be embodied in other forms without being limited to the embodiment set forth herein. Rather, these embodiments are provided so that this disclosure will be thorough and complete, and will fully convey the scope of the disclosure to those skilled in the art.

In describing the accompanying drawings, similar reference symbols are used for similar components. In the attached drawings, dimensions of constituent elements are to be exaggerated compared to the real dimensions for clarity of the present disclosure. It will be understood that, although the terms first, second, etc. may be used herein to describe various elements, these elements should not be limited by these terms. These terms are only used to distinguish one element from another. For example, without departing from the scope of example embodiments, a first element may be termed a second element, and similarly, a second element may be termed a first element. A singular expression includes a plural expression unless definitely defined otherwise on the context.

It will be further understood that the terms “comprises”, “comprising”, “includes”, and/or “including”, when used herein, specify the presence of stated features, integers, steps, operations, parts and/or combinations thereof, but do not preclude the presence or addition of one or more other features, integers, steps, operations, elements, components and/or groups thereof. Further, a portion such as a layer, a film, a region, a plate, etc. is located “on” another portion, this includes a case where it is located “directly on” the other portion as well as a case where another portion is located therebetween. In contrast, a portion such as a layer, a film, a region, a plate, etc. is located “under” another portion, this includes a case where it is located “directly under” the other portion as well as a case where another portion is located therebetween.

In the present application, it is to be understood that the terms such as “including” or “having”, etc., are intended to indicate the existence of the features, numbers, operations, actions, components, parts, or combinations thereof disclosed in the specification, and are not intended to preclude the possibility that one or more other features, numbers, operations, actions, components, parts, or combinations thereof may exist or may be added.

Unless defined otherwise, all figures, values and/or expressions used for amounts of components, reaction conditions, polymer compositions, and combination products used in the present disclosure are approximate values on which various uncertainty of measurement generated to these values is reflected among essentially different figures. For this reason, in all cases, it should be understood to being modified by a term of “about”. Further, when a numerical range is disclosed in the present disclosure, this range is continuous, and includes all values from a minimum value to a maximum value in this range unless designated otherwise. Furthermore, when this range indicates an integer, the range includes all integers from a minimum value to a maximum value unless designated otherwise.

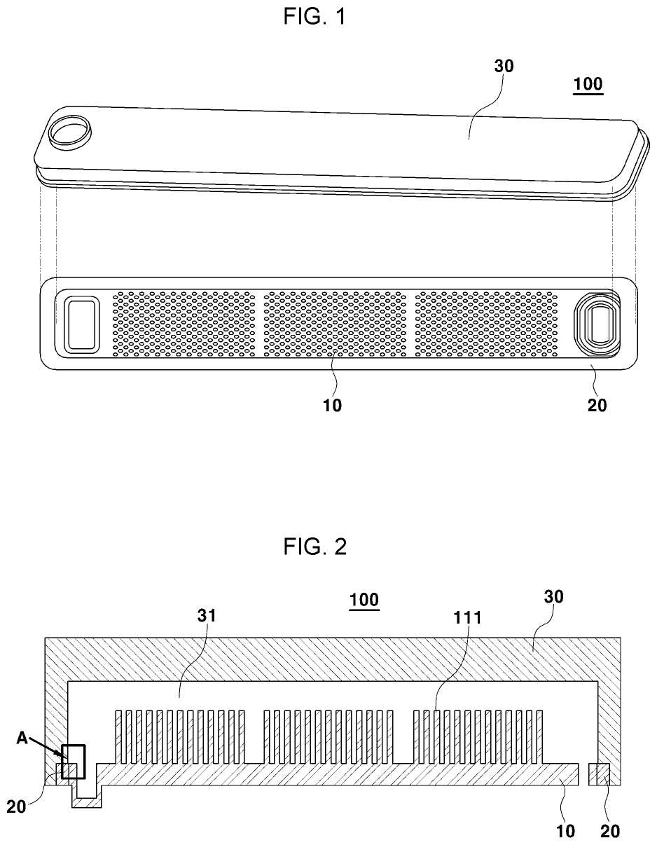

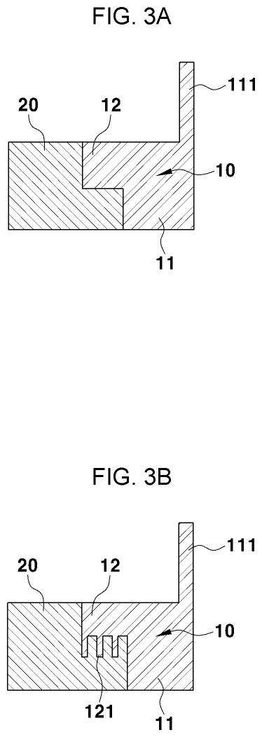

The present disclosure relates to a cooler for a power module. Hereinafter, the present disclosure will be described in greater detail with reference to the accompanying drawings. Here, FIG. 1 is a figure schematically illustrating a cooler for a power module according to the present disclosure. FIG. 2 is a schematic cross-sectional view of the cooler for a power module according to the present disclosure.

Referring to FIGS. 1 and 2, a configuration of the cooler 100 for a power module according to the present disclosure will be described in greater detail as follows.

The cooler 100 for a power module according to the present disclosure may be formed of a metal of a copper material, and may be made up of a cooling fin 10 that includes a body part having a plate form and a protrusion part protruding from an outer side of the body part, a bonding body 20 which is formed of an aluminum alloy material, includes an inner surface corresponding to a form of the protrusion part, and in which the protrusion part and the inner surface are coupled to each other, and a housing 30 that is formed of the same material as the aluminum alloy, an upper surface of which is joined with an outer side of the bonding body and in an inner portion of which a housing space 31 is formed.

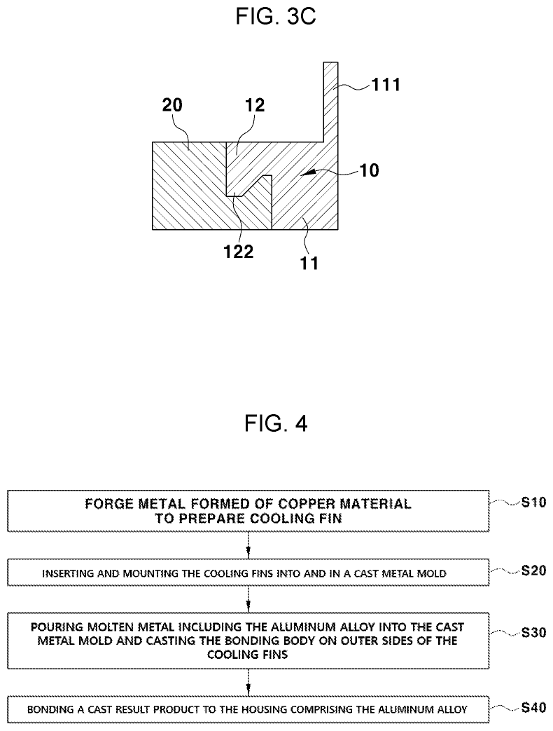

Referring to FIGS. 2 and 3A, the cooling fin 10 may include a body part 11 and a protrusion part 12. Here, FIGS. 3A to 3C are views enlarging part A illustrated in FIG. 2. To be specific, FIGS. 3A to 3C schematically illustrate a shape of a protrusion part according to an exemplary embodiment of the present disclosure.

The cooling fin 10 may include a metal for a copper material. To be specific, the metal for the copper material may be an alloy made up of copper (Cu) 99.9 wt % or more, and phosphorus (P) 0.004 wt % or lower. To be more specific, a Cu 1100 alloy having high purity may be used as the metal for the copper material.

The metal for the copper material may have thermal conductivity of 400 to 500 W/mK. Thus, the cooling fin 10 may have thermal conductivity of 400 to 500 W/mK.

The body part 11 may be formed in a plate-like structure. The body part 11 may be formed such that a plurality of first protrusion parts 111 protrude from an upper surface of the plate-like structure at regular intervals.

The protrusion part 12 may be formed to protrude from an outer side of the body part 11.

The protrusion part 12 may be formed on a lower side of the outer side to protrude along a circumference of the body part 11 as a whole.

In the cooling fin 10, a power module may be attached to a lower surface of the body part 11 which is located on the opposite side of the first protrusion parts 111. The present disclosure is configured such that the power module is cooled through heat exchange with an antifreeze which flows toward the cooling fin 10, and such that, as efficiency of heat exchange with the power module is enhanced, cooling performance may be improved.

In the present disclosure, the protrusion part 12 may be implemented in various shapes in order to increase a bonding force between the heterogeneous materials.

Specifically, as illustrated in FIG. 3A, the protrusion part 12 may be formed to protrude such that a cross section becomes a quadrilateral shape.

According to another embodiment, as illustrated in FIG. 3B, the protrusion part 12 may be formed with at least one or more second protrusions 121 on a lower surface thereof. In this case, the protrusion part 12 may be formed with the plurality of second protrusions 121 on the lower surface thereof at regular intervals.

According to another embodiment, as illustrated in FIG. 3C, the protrusion part 12 may be formed with a curved surface 122 in which a part of a lower surface thereof is indented on a lower surface thereof at a fixed depth.

The bonding body 20 may include the aluminum alloy. To be specific, the aluminum alloy may be an alloy made up of 1.5 to 3.5 wt % of copper (Cu), 9.6 to 12.0 wt % of silicon (Si), 0.3 wt % or less of magnesium (Mg), 1.0 wt % or less of zinc (Zn), 1.3 wt % or less of iron (Fe), 0.5 wt % or less of manganese(Mn), 0.5 wt % or less of nickel (Ni), 0.3 wt % or less of tin (Sn), and a balance of aluminum (Al). To be more specific, an ADC12 alloy may be used as the aluminum alloy.

The bonding body 20 may include an inner surface corresponding to the shape of the protrusion part 12, and the protrusion part 12 and the inner surface of the bonding body 20 may be coupled.

Here, the coupling of the heterogeneous material may be embodied by insert casting to be described below.

The bonding body 20 may have a structure in which it encloses an outer side of the cooling fin 10.

The bonding body 20 may be a region that fixes the cooling fin 10 and that is joined with the housing 30 formed of a different material.

The housing 30 may be made up of the same material as the aluminum alloy. To be specific, the aluminum alloy may be alloy made up of 1.5 to 3.5 wt % of copper (Cu), 9.6 to 12.0 wt % of silicon (Si), 0.3 wt % or less of magnesium (Mg), 1.0 wt % or less of zinc (Zn), 1.3 wt % or less of iron (Fe), 0.5 wt % or less of manganese(Mn), 0.5 wt % or less of nickel (Ni), 0.3 wt % or less of tin (Sn), and a balance of aluminum (Al). To be more specific, an ADC12 alloy may be used as the aluminum alloy.

The housing 30 may be formed therein with a housing space 31. The housing space 31 may be one in which the first protrusion parts 111 may be housed.

The upper surface of the housing 30 may be bonded with an outer side of the bonding body 20. Here, the bonding may be embodied by brazing or laser welding.

The cooler 100 for a power module according to the present disclosure may be configured such that the housing 30 and the cooling fin 10 are bonded by the bonding body 20, a cooling channel may be formed between the housing space 31 and the plurality of first protrusion parts 111.

In another viewpoint, the present disclosure relates to a method of manufacturing a cooler for a power module. Hereinafter, the present disclosure will be described in a greater detail with reference to the attached drawings. In the manufacturing method, concrete descriptions of configurations of the cooling fin 10, the bonding body 20, and the housing 30 will be omitted when they are identical with the foregoing in the cooler 100 for a power module.

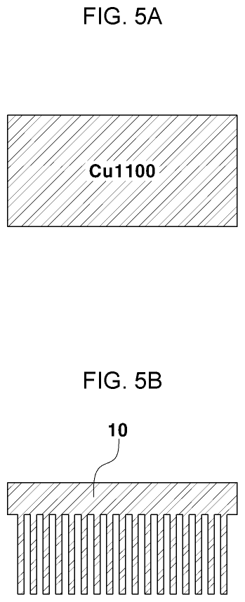

FIG. 4 is a flow chart illustrating the method of manufacturing a cooler for a power module according to the present disclosure. Referring to FIG. 4, the method of manufacturing a cooler for a power module according to the present disclosure is the method of manufacturing a cooler, and includes a step S10 of forging a metal formed of the copper material to prepare a cooling fin, a step S20 of inserting and mounting the cooling fin into and in a casting die, a step S30 of pouring a molten metal including the aluminum alloy into the casting die and casting the bonding body on an outer side of the cooling fin, and a step S40 of bonding the cast result to the housing including the aluminum alloy.

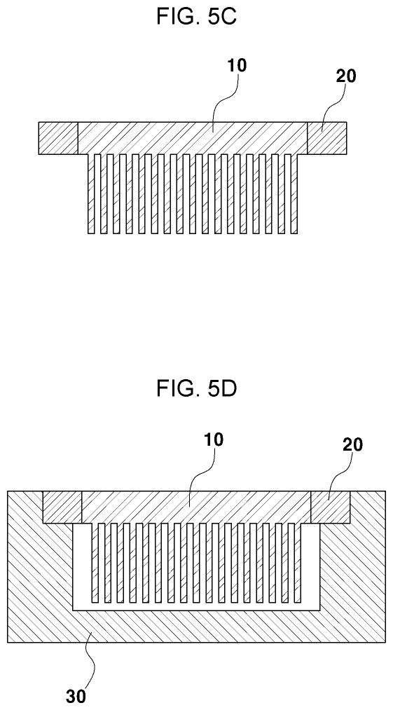

Each of the steps of the method of manufacturing a cooler for a power module according to the present disclosure will be described as follows. FIG. 5 illustrates each of the steps of the method of manufacturing a cooler for a power module.

First, in step S10, as illustrated in FIGS. 5A, the metal formed of the copper material may be prepared. Here, the metal formed of the copper material may be an alloy made up of 99.9 wt % or more of copper (Cu) and 0.004 wt % or less of phosphorus (P). in greater detail, a Cu 1100 alloy having high purity may be used as the metal for the copper material.

Subsequently, as illustrated in FIGS. 5A, the metal formed of the copper material may be forged to prepare the cooling fin 10. The forging could be performed by preheating the forging die at a temperature of 200 to 300° C., and applying a forging pressure to 500 tons or more.

Here, the forging is a method known from those skilled in the art, and the concrete method thereof will be omitted.

Continuously, in step S20, the cooling fin may be inserted into and mounted in the cast metal mold.

Subsequently, in step S30, first, the cooling fin 10 may be heated up to a temperature of 150° C. or higher. Subsequently, the molten metal including the aluminum alloy may be poured into the cast metal mold, and casted the bonding body 20. At this time, the temperature of the cast metal mold may be preheated at 200 to 300° C., and the casting could to performed by applying a casting pressure up to 500 tons or more. Here, the aluminum alloy could be an alloy formed of 1.5 to 3.5 wt % of copper (Cu), 9.6 to 12.0 wt % of silicon (Si), 0.3 wt % or lower of magnesium (Mg), 1.0 wt % or lower of zinc (Zn), 1.3 wt % or lower of iron (Fe), 0.5 wt % or lower of manganese(Mn), 0.5 wt % or lower of nickel (Ni), 0.3 wt % or lower of tin (Sn), and a balance of aluminum (Al). To be more specific, an ADC12 alloy may be used as the aluminum alloy.

To be specific, as illustrated in FIG. 5C, the bonding body 20 may be casted on the outer side of the cooling fin 10, thereby forming a cast product.

In the present disclosure, the high-pressure casting process may particularly use a die casting process as a method well-known in the past.

Finally, in step S40, the cast product may be solidified, and was bonded to the housing. The housing may include the aluminum alloy. Here, the aluminum alloy may be an alloy formed of 1.5 to 3.5 wt % of copper (Cu), 9.6 to 12.0 wt % of silicon (Si), 0.3 wt % or less of magnesium (Mg), 1.0 wt % or lower of zinc (Zn), 1.3 wt % or lower of iron (Fe), 0.5 wt % or lower of manganese (Mn), 0.5 wt % or lower of nickel (Ni), 0.3 wt % or lower of tin (Sn), and a balance of aluminum (Al). To be more specific, an ADC12 alloy may be used as the aluminum alloy.

To be specific, as illustrated in FIG. 5C, the housing 30 and the cooling fin 10 may be bonded by the bonding body 20.

In this case, the bonding process may particularly use brazing or laser welding as a method well-known from the prior art.

In the above step, when the brazing process is used, it may be performed at a temperature of 470 to 480° C.

Further, in the above step, when the laser welding process is used, it may be performed at an output of 2.8 to 4.5 kW.

The above step is the process of bonding the bonding body 20 and the housing 30 formed of the same material, and has an advantage in that good bonding quality can be secured and bonding strength is excellent compared to conventional bonding of heterogeneous materials.

Hereinafter, the present disclosure will be described through a concrete embodiment in greater detail. The embodiment described below is merely illustrative in order to help understanding of the present disclosure, and the scope of the present disclosure is not limited thereto.

### EXAMPLE

First, a cooling fin formed of Cu was made through a method of forging a Cu 1100 billet, and was inserted into a cast metal mold. Then, a high-pressure cast molding was performed by injection of an ADC 12 alloy, thereby preparing a composite material cooling fin of an Al—Cu form.

Here, compositions of the Cu 1100 billet and the ADC 12 alloy were given as in Table 1. In this case, the forging method preheats the temperature of the forging die to a temperature of 200 to 300° C., and applies the forging pressure to 500 tons or higher.

Further, the high-pressure cast molding heated the cooling pins at a temperature of 150° C. or higher, the cast metal mold was preheated to a temperature of 200 to 300° C., and the casting pressure was applied up to 500 tons or higher.

Subsequently, the manufactured cooling fins formed of the composite material were integrated into the housing through the laser welding or the brazing bonding. In this case, a power module cooler having a coolant channel inside the housing was finally manufactured.

Here, in the case in which the bond condition is the brazing, it can be performed at a temperature of 470 to 480° C., and in the case in which the bond condition is the laser welding, it can be performed with an output of 2.8 to 4.5 kW

TABLE 1

| Component | Cu | Si | Mg | Zn | Fe | Mn | Ni | Sn | P | Al |
|---|---|---|---|---|---|---|---|---|---|---|
| Cu 1100 | 99.9 or more | — | — | — | — | — | — | — | 0.004 or less | — |
| ADC12 | 1.5 to 3.5 | 9.6 to 12.0 | 0.3 or less | 1.0 or less | 1.3 or less | 0.5 or less | 0.5 or less | 0.3 or less | — | Balance |

### Comparative Example

Conventional forged cooling fins were manufactured, and bonded to a housing formed of an ADC12 material. Thereby, a power module cooler in which coolant channels were present in a housing due to a coolant channel was finally manufactured.

Subsequently, cooling efficiencies between the embodiment and the comparative example were measured.

As a result of the measurement, compared to the comparative example using the Al forged cooling fins, the embodiment could improve a cooling efficiency to 14% when cooling a single surface, and to 23% when cooling both of surfaces.

This increases cooling efficiency due to the cooling fins using a Cu 1100 material having thermal conductivity of about 400 W/mK, compared to the forged cooling fins using an Al060 material having thermal conductivity of about 190 W/mK.

Therefore, the cooler for a power module according to the present disclosure uses the cooling fins having high thermal conductivity to reduce an operation temperature of the power module, and thereby it is possible to expect a cost saving effect through a reduction in the number of power modules or a down grade of the specification.

Further, a method of manufacturing a cooler for a power module according to the present disclosure includes: forging a metal of a copper material to make cooling fins; insert casting a bonding body including aluminum on outer sides of the cooling fins, thereby forming a cast product; and bonding the cast product to a housing including aluminum.

Through this processes, the cooling fins and the housing are changed by bonding of a homogeneous material at the cooler for the power module, so that there is an effect capable of securing a bonding quality.

Although the exemplary embodiments of the present disclosure have been described for illustrative purposes, those skilled in the art will appreciate that various modifications, additions, and substitutions are possible, without departing from the scope and spirit of the present disclosure as disclosed in the accompanying claims.

What is claimed is:

1. A cooler for a power module, the cooler comprising:
one or more cooling fins which comprise a body part which comprise 1) a copper material and comprising and 2) a protrusion;
a bonding body comprising an inner side corresponding to a shape of a cooling fin protrusion so that cooling fin protrusions are coupled with the inner side; and
a housing comprising an upper surface bonded with an outer side of the bonding body, and having a housing space formed therein.

2. The cooler for a power module of claim 1 wherein the bonding body and the housing are formed of an aluminum alloy.

3. The cooler for a power module according to claim 1, wherein the body part has a plurality of first protrusions formed on an upper surface thereof so as to protrude at regular intervals.

4. The cooler for a power module according to claim 1, wherein the protrusions are formed to protrude along a circumference of the body part on a lower side of the outer side on the whole.

5. The cooler for a power module according to claim 1, wherein the protrusions are formed to protrude, with the cross section thereof being rectangular.

6. The cooler for a power module according to claim 1, wherein the protrusion has one or more second protrusions on a lower surface thereof and/or the protrusion has a plurality of second protrusions formed on a lower surface thereof at regular intervals.

7. The cooler for a power module according to claim 1, wherein the protrusion has a curved surface in a form in which a part of a lower surface thereof is recessed at a given depth.

8. The cooler for a power module according to claim 1, wherein the bonding body has a structure that encloses outer sides of the cooling fins.

9. The cooler for a power module according to claim 1, wherein the metal formed of a copper material comprises an alloy formed of 99.9 wt % or more of copper (Cu) and 0.004 wt % or less of phosphorus (P).

10. The cooler for a power module according to claim 1, wherein the aluminum alloy comprises an alloy formed of 1.5 to 3.5 wt % copper (Cu), 9.6 to 12.0 wt % silicon (Si), 0.3 wt % or less magnesium (Mg), 1.0 wt % or less zinc (Zn), 1.3 wt % or less iron (Fe), 0.5 wt % or less manganese (Mn), 0.5 wt % or less nickel (Ni), 0.3 wt % or less tin (Sn), and a balance of aluminum (Al).

11. The cooler for a power module according to claim 1, wherein the cooling fins have thermal conductivity of 400 to 500 W/mK.

12. The cooler for a power module according to claim 2, wherein the first protrusions are housed in the housing space.

13. A method of manufacturing the cooler described in claim 1, the method comprising:
forging a metal of a copper material to make the cooling fins;
inserting and mounting the cooling fins into and in a cast metal mold;
pouring molten metal including the aluminum alloy into the cast metal mold and casting the bonding body on outer sides of the cooling fins, thereby forming a cast product; and
bonding the cast product to the housing comprising the aluminum alloy.

14. The method according to claim 13, wherein the forging comprises preheating the forging die to a temperature of 200 to 300° C. and applying a forging pressure to 500 tons or higher.

15. The method according to claim 13, wherein the casting uses a die casting process.

16. The method according to claim 13, wherein the casting is performed after heating the cooling fins at a temperature of 150° C. or higher.

17. The method according to claim 13, wherein the casting comprises preheating a temperature of the cast metal mold to 200 to 300° C. and applying a casting pressure up to 500 tons or higher.

18. The method according to claim 13, wherein the bonding of the housing uses brazing or laser welding.

19. The method according to claim 18, wherein, in the bonding of the housing, the brazing is performed at a temperature of 470 to 480° C.

20. The method according to claim 18, wherein, in the bonding of the housing, the laser welding is performed with an output of 2.8 to 4.5 kW.
